(19) United States
(12) Patent Application Publication
(10) Pub. No.: US 2025/0356077 A1
(43) Pub. Date: Nov. 20, 2025

(54) META-LEARNING AND DIGITAL TWIN DATA GENERALIZATION FOR AIOPS MODEL

(71) Applicant: INTERNATIONAL BUSINESS MACHINES CORPORATION, ARMONK, NY (US)

(72) Inventors: Xi Yang, Apex, NC (US); Larisa Shwartz, Greenwich, CT (US); Saurabh Jha, White Plains, NY (US); Chandrasekhar Narayanaswami, Wilton, CT (US); Bekir Oguzhan Turkkan, Amherst, NY (US); Paulito Palmes, Dublin (IE); Frank Bagehorn, Dottikon (CH)

(21) Appl. No.: 18/668,082

(22) Filed: May 17, 2024

(51) Int. Cl. G06F 30/20

(52) U.S. Cl. CPC G06F 30/20

(57) ABSTRACT

A method, computer system, and a computer program product are provided. A first digital twin that models a first computing application being carried out in a first computing configuration is generated. The first digital twin replicates settings of the first computing configuration. A second digital twin is generated by altering the first digital twin. Respective time series data from the first digital twin, from the second digital twin, and from the first computing configuration are gathered. Drift in the gathered time series data is detected such that that different groups of data are produced. An artificial intelligence for information technology machine learning model (AIOPs model) is trained by implementing meta-learning domain generalization and by using training data divided according to the different groups of data.

### STATEMENT REGARDING PRIOR DISCLOSURE BY THE INVENTORS

The following disclosure is submitted under 35 U.S.C. 102(b)(1)(A): DISCLOSURE: YANG et al., “Meta-learning Generalized AIOps Models for Multi-cloud Computer using Digital Twins”, CASCON '23: Proceedings of the 33^{rd} Annual International Conference on Computer Science and Software Engineering, September 2023, 5 pages.

### BACKGROUND

The present invention relates generally to the fields of artificial intelligence operations (AIOps) models, multi-cloud computing, digital twins, and meta-learning for machine learning.

### SUMMARY

According to one exemplary embodiment, a computer-implemented method is provided. A first digital twin that models a first computing application being carried out in a first computing configuration is generated. The first digital twin replicates settings of the first computing configuration. A second digital twin is generated by altering the first digital twin. Respective time series data from the first digital twin, from the second digital twin, and from the first computing configuration are gathered. Drift in the gathered time series data is detected such that that different groups of data are produced. An artificial intelligence for information technology machine learning model (AIOPs model) is trained by implementing meta-learning domain generalization and by using training data divided according to the different groups of data. A computer system and computer program product corresponding to the above method are also disclosed herein.

### BRIEF DESCRIPTION OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description.

FIG. 1 illustrates a framework for using digital twins and meta-learning generalization to train an AIOps model for multi-cloud computing according to at least one embodiment.

FIG. 2 illustrates details about drift detection according to at least one other embodiment that is part of the framework shown in FIG. 1.

FIG. 3 illustrates details about meta-learning according to at least one other embodiment that is part of the framework shown in FIG. 1.

FIG. 4 illustrates a networked computer environment in which AIOps model enhancement is performed according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

The following described exemplary embodiments provide a computer system, a method, and a computer program product for digital twins processes. Multi-cloud computing is a vitally important topic from a technical perspective because it leads to resiliency, availability, and security for computing applications. Artificial intelligence for information technology (IT) operations is referred to as AIOps and uses big data, analytics, and machine learning to assist with various IT tasks. A machine learning model trained to perform AIOps tasks is referred to as an AIOps model.

In some instances, AIOps models have been generated to track and model the performance and settings of one or more computing applications being performed in a cloud computing configuration. Due to the vast number of configurations among cloud providers, it is quite challenging to migrate AIOps models across different clouds. Although it is possible to train these models from scratch on the target cloud, this process can be time consuming and prone to delays. Creating a generalized AIOps model from the original cloud that can be seamlessly applied to target cloud with minimal to zero-shot observations is advantageously presented with the embodiments described herein. To achieve this goal, the framework presented herein harnesses the potential of digital twins to enhance data generalization. Additionally, the framework employs meta-learning techniques to ensure effective model generalization across different cloud environments.

Multi-cloud computing is an essential topic for IT landscape and businesses, offering a variety of advantages. From a business perspective, it empowers organizations to avoid vendor lock-in and provides the flexibility to choose among different cloud providers. In spot markets, multi-cloud computing facilitates economical migration of “bursty” applications. From a technical perspective, multi-cloud computing ensures resiliency, availability, and flexibility. Multi-cloud computing helps safeguard against cloud provider outages, optimizes capacity by leveraging regional cloud providers, and enables the use of best-of-breed services. Thus, the practice promotes productivity, which opens up opportunities for different applications to utilize the cloud platform that best matches their requirements.

When operating in cloud computing, various AIOps models can be developed based on IT operational data (e.g., metrics, logs, traces) to automate and streamline operational workflows, e.g., anomaly detection, root cause analysis, auto-remediation, resource management, etc. The AIOps models effectively reduce the cognitive load and improve productivity when exploiting the extensive and diverse operational data generated during development operations (DevOps) activities. For example, AIOps models efficiently identify anomalies, locate root causes, automatically resolve problems, and manage cloud resources, all without requiring manual operational intervention. The incorporation of data-driven AIOps models plays a critical role in expediting and automating the resolution of intricate IT environment problems, thereby reducing the management complexity for human operators.

When migrating applications from the original cloud to another cloud, the collected observability data is susceptible to experiencing distribution drifts. This susceptibility is due to the diverse compute, network, storage, software, and hardware configurations among different cloud providers. Therefore, directly applying the AIOps model learned from one cloud to another would likely result in failure due to the discrepancies in data distributions.

The present embodiments disclose the development of an AIOps model that is readily adaptable to new environments. Although it is feasible to train a selected model from scratch using newly collected data from the target cloud, it can be expensive due to the time-consuming data collection process. Transferring or generalizing a pre-trained model not only expedites the learning process but also enhances learning performance by incorporating a broader range of data. To achieve this goal, the present embodiments provide a framework that achieves prompt adaptation with minimal to zero-shot observations by treating the generation of the new AIOps model to be directly applicable for the new cloud computing configuration as an out-of-distribution generalization problem.

In multi-cloud computing, various cloud providers offer diverse compute, network, storage, software, and hardware configurations, which commonly leads to altered behavior while serving the same application. Some examples of these challenges are described below.

In a first example, a containerized application is deployed on two clusters with different configurations: Cluster A has 12 virtual central processing units (VCPUs) and 48 GiB of memory, and Cluster B has 24 VCPUs and 96 GiB of memory. Due to the larger number of resources in Cluster B, the latency decreases for most of the services as expected, while latency increased for a few of the services. Therefore, it is challenging to anticipate how different computing configurations offered by varying cloud providers will impact the data distribution.

In another example, a big cluster has a total of 24 VCPU with 94 GiB of memory, and a small cluster has a 24 VCPU with 46 GiB memory. While the small cluster has relatively lower calls per second (CPS), its CPS significantly dropped closed to zero when variations over its configurations in VCPUs, memory, and network are manually introduced. As a comparison, when such variations are introduced to the big cluster, the CPS turns out to be even larger. Therefore, a specific AIOps model learned/trained merely from the observed data of the original configuration in the small cluster is not enough to capture the various patterns under other possible configurations in both clusters. This scenario presents notable challenges, as a model that performs well when evaluated on the original cloud may not necessarily perform as effectively over the target cloud due to the differing distributions.

Variations in configurations may lead to distribution drifts in the gathered observability data during the migration of AIOps models from a source cloud to a target cloud. Although the model can be retrained using newly collected data from the target cloud, data availability remains a significant obstacle, since the process of collecting sufficient data is inherently time-consuming. Delays in collecting authentic data potentially leads to delays in the model learning. Moreover, there is often a strong preference for having a model readily available for providing predictions before any observations from the target cloud become available, which poses additional challenges in ensuring the seamless and efficient deployment of AIOps solutions across various cloud environments.

The drifts for AIOps models in multi-cloud computing can be modeled as a problem of out-of-distribution generalization. Machine learning models are susceptible to data distribution shifts in training data. The present embodiments implement principles of data generalization and model generalization to help overcome problems with these shifts in the training data.

The present embodiments implement data augmentation techniques to enhance data generalization by generating populations different from the training distribution, particularly in scenarios where access to data from unknown target distributions is limited. The advancement of simulation technology has substantially improved data augmentation, enabling the generation of synthetic data that closely resembles real operational environments. This capability has become a key driver behind the generalization capability of industrial AI solutions for real scenarios. In recent years, digital twins have demonstrated success in automating data acquisition and processing, with advanced simulation technology. A digital twin is a virtual representation of a physical object, meticulously designed to replicate the high-fidelity attributes of its real-world counterpart within a virtual space. Digital twins can accurately simulate complex machinery, and thereby enable the generation of realistic synthetic datasets. The present embodiments include the integration of simulated data with available real-world data, so that the training dataset is enriched with more diverse distributions, providing the potential to learn a more robust AIOps model. This enrichment not only benefits generalizing to unseen distributions in the target cloud but also potentially improves performance in the original cloud.

However, while digital twins offer significant benefits, they also come with challenges, such as addressing data quality and security, handling increased power and storage demands, and integrating with existing infrastructures, which are under active explorations in the field. Despite the enriched distributions, directly using mixed data distributions as input for a single model might still limit its capability to handle unseen new distributions. To address this issue, the present embodiments also incorporate model generalization to supplement the data generalization.

To bolster the capacity of the AIOps model for handling unseen distributions, the present embodiments facilitate model generalization through meta-learning, which is also known as “learning to learn.” By training the AIOps model with diverse learning tasks, meta-learning enables the model to swiftly adapt to new tasks with limited observations. In order to address the distribution drifts, each distribution is modeled in the training data as an individual learning task. An AIOPs model is derived that exemplifies robust generalization capabilities through adept adaptation to new tasks characterized by various distributions.

In the context of multi-cloud computing, where migrating to a target cloud occurs without prior information about the computing distribution and settings of the target cloud, at least some of the present embodiments produce an AIOps model that adapts through zero-shot observations from the target cloud. To address this challenge, the present embodiments employ meta-learning domain generalization (MLDG). Unlike utilizing a specific model tailored for generalization, MLDG serves as a model-agnostic algorithm that enhances the robustness of various AIOps models (e.g., supervised, unsupervised, reinforcement learning). By capturing shared patterns across different distributions, MLDG can filter out the impact of infrastructure and software over the application performance. This capturing and filtering allows various generalized AIOps models to be learned and facilitates their transfer across different computing and cloud configurations. However, meta-learning can only effectively capture distribution drifts and achieve a more robust model if the input data demonstrates a certain level of generalization. If all input data originates from a single distribution, then the algorithm may not sufficiently learn the desired robustness. To address this limitation, the present embodiments incorporate data generalization along with the meta-learning.

Relying solely on either data or model generalization is insufficient for cloud migration inferencing. Therefore, the present embodiments leverage the strengths of both approaches by effectively combining them. The present embodiments achieve a robust generalization and adaptation to different models. The present embodiments harness the capabilities of both digital twin and meta-learning to achieve data and model generalization simultaneously, aiming for a model-agnostic framework.

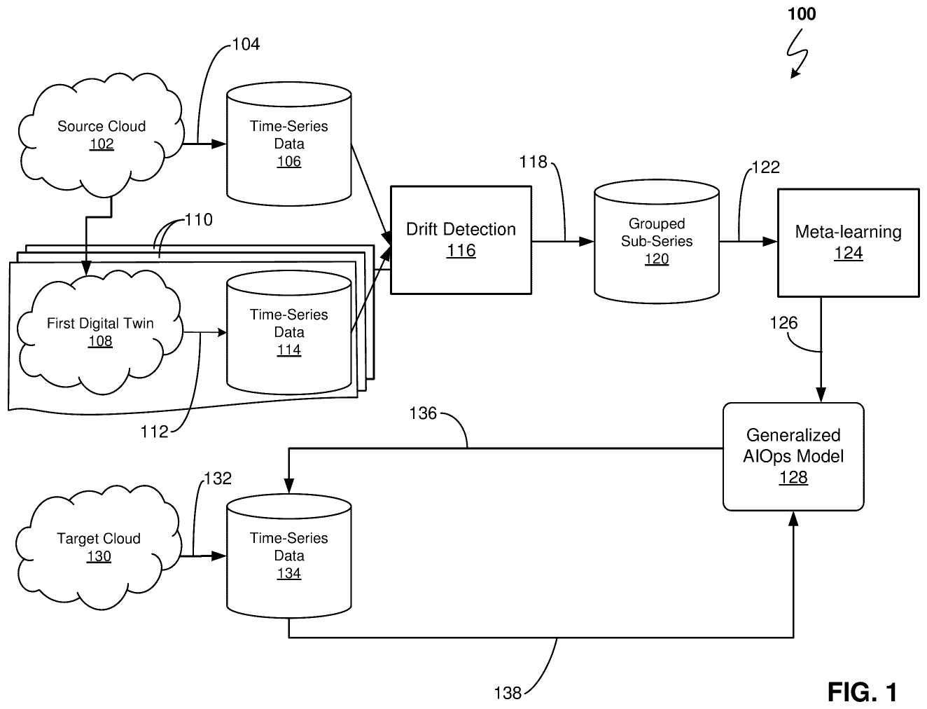

The present embodiments include a framework 100 as illustrated in FIG. 1, which includes four major components including a) Generation of digital twins for simulating data under different configurations to achieve data generalization; b) Detection of distribution drifts over both original and simulated time-series data to learn the groups of sub-series with different distributions; c) Meta-Learning for a generalized model to capture shared patterns across different sub-series groups to achieve model generalization; and d) Model Adaptation for fine-tuning the model given the incrementally collected data from the target cloud.

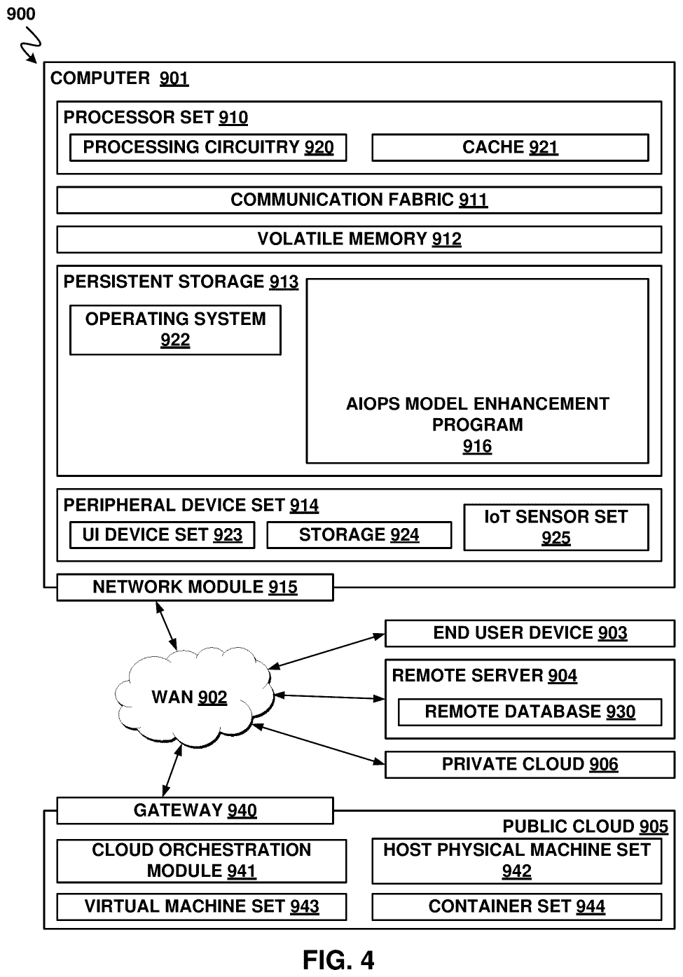

Observing the application under different cloud configurations is vital to identify possible distribution drifts due to migration. To this end, digital twins provide a low risk environment to simulate the application behavior over different configurations without causing any disruptions in the original environment. The framework 100 shown in FIG. 1 includes a source cloud 102 from which a first data collection 104 occurs to obtain authentic time-series data 106. One or more first computer applications are performed in the source cloud 102 and various information and/or data, e.g., metrics, logs, traces, etc. from the operation of the one or more first computer applications are gathered in the first data collection 104 and are used to generate the first digital twin 108. Information provided by a provider of the source cloud 102 is also useable to generate this first digital twin 108. The first digital twin 108 is designed as a virtual representation of the source cloud 102 which includes various physical objects such as computers, processors, memories, and applications operating thereon. The first digital twin 108 is intended to be a meticulously designed replication of the source cloud 102 and within a virtual space to have some or all high-fidelity attributes of the real-world computing application being hosted by and operated on the source cloud 102. Thus, the first digital twin 108 exists as computer code in a program such as the AIOps enhancement program 916 of the computer 901 shown in FIG. 4. The first digital twin 108 is based on mirroring the real-time data collected in first data collection 104. In at least some embodiments, the first digital twin 108 replicates settings and configurations such as network, hardware, software, data architecture, instances, physical resources on those instances, etc. of the source cloud 102.

Informed with the real-time data collected from the physical object, digital twins serve as a powerful tool for conducting simulations, analyzing performance issues, and generating potential improvements. The insights gained through these processes can then be applied back to the original physical object, leading to enhanced research and development (R&D) efforts and increased operational efficiency. Due to its versatility, digital twins have found extensive applications across various sectors, including industrial production, healthcare services, smart cities, aerospace, and the retail industry. Specifically, in the context of industry applications, suggestions have been given to use digital twins to data acquisition and processing while introducing a multi-mode data acquisition method. For example, digital twins have been employed to achieve more robust and reliable anomaly detection, which is a critical component for quality assurance. Among them, digital twins were employed to artificially generate a large dataset simulating the normal operation of the machinery. The simulated data is integrated into the available real-world data to enrich the training dataset, which is beneficial for deriving a more robust machine learning model. Given the data augmented by digital twins, improved anomaly detection performance was demonstrated, with the recall improved by 3.75% and the precision improved by 18%.

By accurately replicating the structural and behavioral characteristics from its original counterpart, i.e., a real twin (RT), a digital twin empowers developers to observe, measure, and model the past, present, and future behaviors of the RT. This capability enables the mitigation of risks through adaptive experimentation, data collection, and hypothesis testing, such as exploring new system configurations. Consequently, digital twins can be instantiated (i.e., replicated) to conduct experiments in controlled and simulated environments, safeguarding the original IT environment from potential disruptions and preserving its integrity. Moreover, since AIOps often relies on data-driven models to expedite and automate the resolution of complex IT problems, the incorporation of digital twins to help with an AIOps model is especially advantageous. This incorporation facilitates the collection of additional data, leading to more robust AIOps models and thereby enhancing the overall efficiency of AIOps practices.

After the generation of the first digital twin 108, the present embodiments include creating alterations starting from the first digital twin. In at least some embodiments, these alterations include one or more steps of using interventions to emulate additional digital twins that are alterations of the first digital twin 108. Additional digital twins 110 are labeled in FIG. 1 and are alterations of the first digital twin 108. In some embodiments, chaos engineering toolkits, such as Chaos Toolkit and LitmusChaos, are employed to adjust available resources, and which result in efficient mimicking of the first digital twin 108 to produce the separate and different additional digital twins 110. In one embodiment, the intervention includes limiting central processing unit (CPU) utilization for the computing application thread by throttling to mimic an infrastructure with a slower CPU. Throttling can include adjusting a clock speed and/or a voltage of a CPU. In some additional and/or alternative embodiments, the intervention includes scaling the initial digital twin (first digital twin 108) to have a different (e.g., larger or smaller) scale. In various embodiments, interventions to generate digital twins are done systematically and/or randomly depending on the use case. For example, to understand the impact of each resource type in application behavior, one can systematically generate interventions; however, random interventions can be employed for data collection purposes. In at least some embodiments, the emulated digital twins (additional digital twins 110) have less resources than the initial digital twin (first digital twin 108). In addition, in some embodiments the interventions are applied in a way that all related computing resources are impacted in the same way. For instance to create a digital twin with less CPU, all cores must be throttled together. The generation of these multiple altered digital twins eventually helps achieve data generalization for improved training of the AIOps model 128. The implementation of diverse or different digital twins helps produce rich data distributions to be used downstream for the meta learning.

Data is collected from the original cloud 102 and from one, some, or all of the various digital twins 108, 110. This data collection can include the data gathering 104 mentioned above and also includes data gathering 112 for the first digital twin 108. Corresponding data gathering steps (similar to the data gathering 112) occur respectively for the additional digital twins 110. One or more simulated computer applications are performed in the various digital twins and various information and/or data, e.g., metrics, logs, traces, etc. from the operation of the one or more first computer applications are gathered in the data gathering/collection. The various types of gathered data (e.g., metrics, logs, traces, etc.) can be converted to and stored as time-series data 106 of the source cloud 102 and as time-series data 114 for the first digital twin 108. Specifically, metrics data is in general directly represented as time-series, so no conversion is necessary. For the data logs, parsing algorithms can be employed to extract log templates, then a sliding window can be employed to slice the logs, within which the similarities versus the extracted templates can be measured and represented as time-series. For data traces, similarly, a sliding window can be applied, and within each window, the stats (e.g., mean, median, std) of the response time can be calculated and converted to time-series. Additional time-series data for the additional digital twins 110 is also gathered, stored, and converted into time series data as necessary.

In stage 116 the data is analyzed to identify/detect any distribution drifts therein. In various embodiments, distribution drifts are detected/identified not only across different time-series but also within individual time-series along the time. At least some of the present embodiments incorporate detecting drifts in both intra-time-series and inter-time-series scenarios, ensuring comprehensive monitoring and adaptation to any potential shifts in the data distributions. Data drift is a change in input data which leads to model performance degradation. Data drift can occur when the data has a variation, e.g., in range of values, which is not expected, e.g., when operating conditions did not change, e.g., observably change.

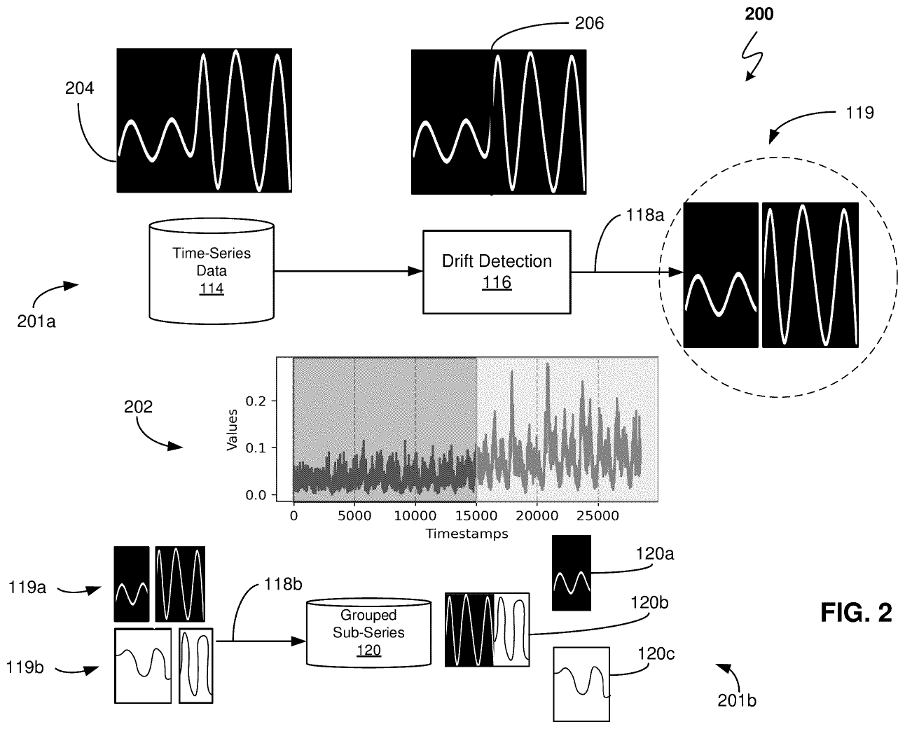

FIG. 2 shows drift detection details 200 about stage 116, drift detection, and associated steps of the framework 100 shown in FIG. 1. Gathered data is illustrated in a data graph 202 that shows numeric values for the y-axis and timestamps for the x-axis. The upper half of the drift detection details 200 shows details about intra-time-series splitting 201a. For this aspect, each time-series is split into sub-series when distribution drifts happen. Such splitting is conducted for all time-series collected from both source cloud 102 and its digital twins 110. The lower half of the drift detection details 200 shows details about inter-sub-series grouping 201b, which aims at grouping the sub-series split from different time-series.

With respect to intra-time-series splitting 201a also referred to as splitting, in some embodiments, distribution drifts are captured within a time-series by employing a sliding window partitioning approach. Depending on the specific use case, for intra-time-series splitting 201a, the time-series can be divided into windows of hourly, daily, or weekly, each with a size denoted as ω. At any given timestamp t, the window is represented as Xₜ={xₜ−ω+1, . . . , xₜ}, where xₜ is the observed metrics at t. To identify potential distribution drifts, a statistical test comparing Xₜ with the prior windows {Xₜ−M, . . . , Xₜ−1} is performed, where M represents the number of previous windows considered in the comparison. Various statistical methods can be used, such as the Kolmogorov-Smirnov (K-S) test, least-squares density difference, maximum mean discrepancy, etc. If a drift is detected at Xₜ, then the data group is split from the prior time-series, resulting in sub-series with different distributions.

In at least some embodiments, the intra-time-series splitting 201a occurs with various time-series data, and as an example the time-series data 114 from the first digital twin 108 is shown. A first data graph excerpt 204 is shown illustrating values of some of the time-series data 114 with respect to a time axis. One or more of the various techniques described above applied during drift detection 116 help to identify the drift. Drift onset 206 is shown in FIG. 2 as being identified in the first data graph excerpt 204 during the drift detection 116. Truncation 118a (shown in FIG. 2) is performed as a sub-type of truncation 118 (shown in FIG. 1) and produces sub-series 119, with the two different sub-series (shown as an example) separated/truncated at the location of the drift onset 206. Although two sub-series are shown in the illustration of sub-series 119 in FIG. 2, in practice the truncation techniques are capable of producing many different sub-series as part of the group.

At least some embodiments include the inter-time-series grouping 201b performed to the various sub-series 119 that are produced via the intra-time-series splitting 201a. Inter-time-series grouping 201b shown in FIG. 2 starts with sub-series produced via the intra-time-series splitting 201a, with this example an upper set of sub-series 119a and a lower set of sub-series 119b being shown. After splitting the sub-series from different time-series in a manner such that many or all of the new individual sub-series exhibit distinct distributions, grouping 118b is performed to ensure that sub-series with similar distributions are categorized together. To achieve this goal, given sub-series 119a and 119b, some embodiments include the application of various statistical tests, (e.g., Kolmogorov-Smirnov (K-S) test, least-squares density difference, maximum mean discrepancy) to measure the distribution between pair-wise sub-series and group the sub-series without significant distribution drifts, or the application of clustering algorithms to divide sub-series into different clusters. This grouping process 118b enables the effective identification and management of sub-series with similar distributions, facilitating more focused analysis. FIG. 2 shows that the grouping 118b produced three different groups of sub-series, namely first group 120a, second group 120b, and third group 120c. These various groups are saved and stored as the grouped sub-series 120 shown in FIGS. 1 and 2.

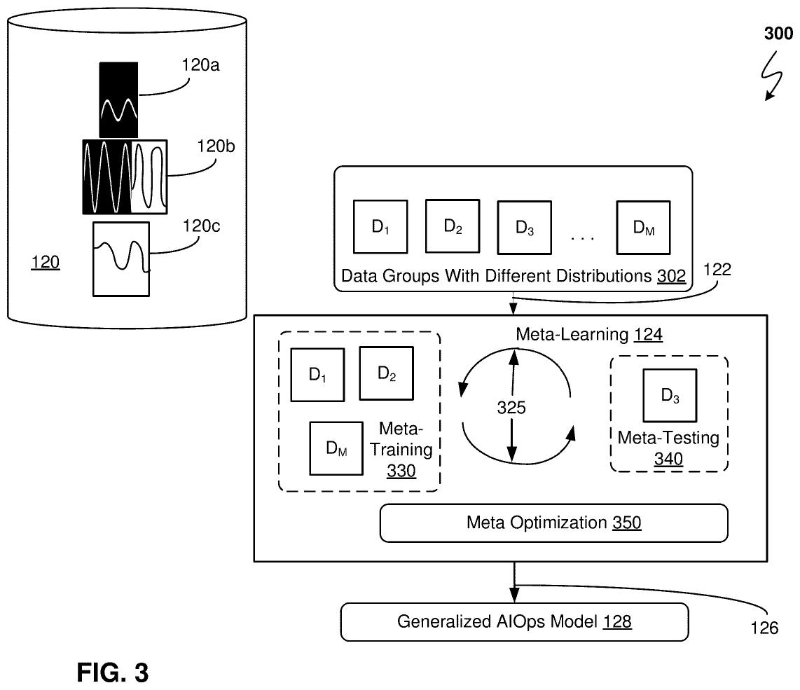

FIG. 3 shows meta-learning details 300 about meta-learning 124 and associated steps shown in FIG. 1. In the context of meta-learning, each sub-series group (e.g., first group 120a, second group 120b, third group 120c) with different distributions is referred to as a “domain”. The sub-series groups are passed as domains 122 from storage in memory at stage 120 to the meta-learning processes at meta-learning 124. Each of the sub-series groups with a different distribution is indicated by a respective domain, e.g., the domains D₁, D₂, D₃, . . . D_{M} shown in the data groups with different distributions 302 in FIG. 3.

Meta-learning introduces a paradigm wherein a machine learning model accumulates experience across multiple learning episodes, encompassing a distribution of related tasks. The machine learning model leverages this experience to bolster the future learning performance. This “learning to-learn” concept offers a host of advantages, including enhanced data and compute efficiency, while also bearing similarity to the learning strategies observed in human and animal learning where improvements occur over both lifetime and evolutionary timescales. Unlike conventional AI approaches, where tasks are tackled from scratch using a fixed learning algorithm, meta-learning focuses on enhancing the learning algorithm itself through the insights gained from multiple learning episodes.

A motivation of the meta-learning 124 of the present embodiments is to develop domain-agnostic models from training domains S (e.g., the domains D₁, D₂, D₃, . . . D_{M}), which can be readily generalized to unseen domains. The meta learning domain generalization can be employed to achieve this development of domain-agnostic models from the training domains S. The meta learning domain generalization is illustrated in Algorithm 1 provided below. The process involves iterative steps of domain splitting 325, meta-training 330, meta-testing 340, and meta-optimization 350 applied to an AIOps model so that a base AIOps model becomes Generalized AIOps model 128. These iterative steps continue until convergence is reached. Upon convergence, the Generalized AIOps model 128 will exhibit strong generalization capabilities across various domains (data distributions) in the training data, enabling the Generalized AIOps model 128 to generalize effectively to unseen distributions in the test domain.

### Algorithm 1 Meta Learning Domain Generalization

Input: Domains S
Init: Model parameters
for ite in iterations do
   Split: S for Meta-train and Meta-test
   Meta-train: Calculating the gradient and updating the model
   Meta-test: Calculating the loss
   Meta-optimization: Updating the model considering the
   combined loss from both Meta-train and Meta-test
end for

In other words, the meta-learning domain generalization includes one or more steps of inputting the time-series data into the AIOps model as separate domains divided according to the detected drift; splitting the separate domains into meta train domains and meta test domains; calculating a gradient and updating the AIOps model for the meta train domains; calculating a loss for the AIOps model for the meta test domains; and updating the AIOps model considering a combined loss from both the meta train domains training and the meta test domains training. In at least some embodiments, the domain splitting 326 occurs randomly to split some of the domains as meta training domains and others of the domains as meta test domains. In at least some embodiments, the number of domains selected for meta training 330 is greater than the number of domains selected for meta testing 340.

In some embodiments, the meta testing 340 includes obtaining a loss by executing the base AIOps model being trained to the one or more domains that were selected for meta testing.

In some embodiments, the meta optimization 350 includes combining the loss from the meta training 330 and from the meta testing 340 for optimization. These two losses (from meta training 330 and from meta testing 340, respectively) are optimized simultaneously in at least some embodiments. Minimizing both/all losses and tuning the optimization so that both/all losses descend in a coordinated way are advantageous. At least some embodiments of the meta optimization 350 include training an objective by gradient descent.

By applying the meta-learning, domain-agnostic patterns across the data with different distributions is captured and applied to the generalized AIOps model 128.

For model adaptation, once the generalized AIOps model 128 is obtained through meta-learning domain generalization, the generalized AIOps model 128 can be seamlessly applied to the target cloud 130 with zero-shot observation. This application produces target cloud inferred data 136 which is compared to actual time-series data 134 that is incrementally collected. As that time-series data 134 is incrementally collected from performing one or more computing applications on the target cloud 130, the generalized AIOps model 128 can be periodically adapted in adaptation 138. This process allows for more fine-grained adaptation to fit the distribution drifts specific to the target cloud 130. By continuously updating the Generalized AIOps model 128, optimal performance and responsiveness to the evolving characteristics of the data of the target cloud 130 are achieved.

In some tests, an anomaly detection (AD) model was taken as a pilot AIOps model. The metrics data collected from applications such as Robot-shop by Instana under two different configurations can mimic the varying behaviors of the original and the target clouds. The direct migration of various AD algorithms across different configurations without any data or model generalization was taken as the baseline. The evaluation metrics, e.g., AUC-ROC and AUC-PR, were used and validated the effectiveness of the framework 100.

The present embodiments provide a framework to address distribution drifts in multi-cloud computing. Specifically, the framework tackles the out-of-distribution encountered by AIOps models during migration from an original cloud to one or more target clouds. To achieve an improved migration, both data generalization through the utilization of digital twins and model generalization using meta-learning techniques are integrated. Through the synergy of data and model generalization, the development of a more robust AIOps model capable of seamless adaptation to the target cloud is achieved. As a starting point, anomaly detection as a pilot AIOps model is achieved within the framework.

The various techniques are implemented via a computer, e.g., via automated action of an AIOps model enhancement program 916 when activated, e.g., via a human-computer interaction.

It may be appreciated that FIGS. 1-3 provide only illustrations of certain embodiments and do not imply any limitations with regard to how different embodiments may be implemented. Many modifications to the depicted embodiment(s), e.g., to particular steps, elements, and/or order of depicted methods or components of the pipeline, may be made based on design and implementation requirements.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 900 in FIG. 4 contains an example of an environment for the execution of at least some of the computer code involved in performing the inventive methods, such as AIOps model enhancement program 916. In addition to model-generated code evaluation with AIOps model enhancement program 916, computing environment 900 includes, for example, computer 901, wide area network (WAN) 902, end user device (EUD) 903, remote server 904, public cloud 905, and private cloud 906. In this embodiment, computer 901 includes processor set 910 (including processing circuitry 920 and cache 921), communication fabric 911, volatile memory 912, persistent storage 913 (including operating system 922 and AIOps model enhancement program 916, as identified above), peripheral device set 914 (including user interface (UI) device set 923, storage 924, and Internet of Things (IoT) sensor set 925), and network module 915. Remote server 904 includes remote database 930. Public cloud 905 includes gateway 940, cloud orchestration module 941, host physical machine set 942, virtual machine set 943, and container set 944.

COMPUTER 901 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 930. As is well understood in the art of computer technology, and depending upon the technology, performance of a computer-implemented method may be distributed among multiple computers and/or between multiple locations. On the other hand, in this presentation of computing environment 900, detailed discussion is focused on a single computer, specifically computer 901, to keep the presentation as simple as possible. Computer 901 may be located in a cloud, even though it is not shown in a cloud in FIG. 9. On the other hand, computer 901 is not required to be in a cloud except to any extent as may be affirmatively indicated.

PROCESSOR SET 910 includes one, or more, computer processors of any type now known or to be developed in the future. Processing circuitry 920 may be distributed over multiple packages, for example, multiple, coordinated integrated circuit chips. Processing circuitry 920 may implement multiple processor threads and/or multiple processor cores, Cache 921 is memory that is located in the processor chip package(s) and is typically used for data or code that should be available for rapid access by the threads or cores running on processor set 910. Cache memories are typically organized into multiple levels depending upon relative proximity to the processing circuitry. Alternatively, some, or all, of the cache for the processor set may be located “off chip.” In some computing environments, processor set 910 may be designed for working with qubits and performing quantum computing.

Computer readable program instructions are typically loaded onto computer 901 to cause a series of operational steps to be performed by processor set 910 of computer 901 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 921 and the other storage media discussed below. The program instructions, and associated data, are accessed by processor set 910 to control and direct performance of the inventive methods. In computing environment 900, at least some of the instructions for performing the inventive methods may be stored in AIOps model enhancement program 916 in persistent storage 913.

COMMUNICATION FABRIC 911 is the signal conduction path that allows the various components of computer 901 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 912 is any type of volatile memory now known or to be developed in the future. Examples include dynamic type random access memory (RAM) or static type RAM. Typically, volatile memory 912 is characterized by random access, but this is not required unless affirmatively indicated. In computer 901, the volatile memory 912 is located in a single package and is internal to computer 901, but, alternatively or additionally, the volatile memory may be distributed over multiple packages and/or located externally with respect to computer 901.

PERSISTENT STORAGE 913 is any form of non-volatile storage for computers that is now known or to be developed in the future. The non-volatility of this storage means that the stored data is maintained regardless of whether power is being supplied to computer 901 and/or directly to persistent storage 913. Persistent storage 913 may be a read only memory (ROM), but typically at least a portion of the persistent storage allows writing of data, deletion of data and re-writing of data. Some familiar forms of persistent storage include magnetic disks and solid state storage devices. Operating system 922 may take several forms, such as various known proprietary operating systems or open source Portable Operating System Interface-type operating systems that employ a kernel. The code included in model-generated code evaluation with AIOps model enhancement program 916 typically includes at least some of the computer code involved in performing the inventive methods.

PERIPHERAL DEVICE SET 914 includes the set of peripheral devices of computer 901. Data communication connections between the peripheral devices and the other components of computer 901 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 923 may include components such as a display screen, speaker, microphone, wearable devices (such as goggles and smart watches), keyboard, mouse, printer, touchpad, game controllers, and haptic devices. Storage 924 is external storage, such as an external hard drive, or insertable storage, such as an SD card. Storage 924 may be persistent and/or volatile. In some embodiments, storage 924 may take the form of a quantum computing storage device for storing data in the form of qubits. In embodiments where computer 901 is required to have a large amount of storage (for example, where computer 901 locally stores and manages a large database) then this storage may be provided by peripheral storage devices designed for storing exceptionally large amounts of data, such as a storage area network (SAN) that is shared by multiple, geographically distributed computers. IoT sensor set 925 is made up of sensors that can be used in Internet of Things applications. For example, one sensor may be a thermometer and another sensor may be a motion detector.

NETWORK MODULE 915 is the collection of computer software, hardware, and firmware that allows computer 901 to communicate with other computers through WAN 902. Network module 915 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 915 are performed on the same physical hardware device. In other embodiments (for example, embodiments that utilize software-defined networking (SDN)), the control functions and the forwarding functions of network module 915 are performed on physically separate devices, such that the control functions manage several different network hardware devices. Computer readable program instructions for performing the inventive methods can typically be downloaded to computer 901 from an external computer or external storage device through a network adapter card or network interface included in network module 915.

WAN 902 is any wide area network (for example, the internet) capable of communicating computer data over non-local distances by any technology for communicating computer data, now known or to be developed in the future. In some embodiments, the WAN 902 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 903 is any computer system that is used and controlled by an end user (for example, a customer of an enterprise that operates computer 901) and may take any of the forms discussed above in connection with computer 901. EUD 903 typically receives helpful and useful data from the operations of computer 901. For example, in a hypothetical case where computer 901 is designed to provide a recommendation to an end user, this recommendation would typically be communicated from network module 915 of computer 901 through WAN 902 to EUD 903. In this way, EUD 903 can display, or otherwise present, the recommendation to an end user. In some embodiments, EUD 903 may be a client device, such as thin client, heavy client, mainframe computer, desktop computer and so on.

REMOTE SERVER 904 is any computer system that serves at least some data and/or functionality to computer 901. Remote server 904 may be controlled and used by the same entity that operates computer 901. Remote server 904 represents the machine(s) that collect and store helpful and useful data for use by other computers, such as computer 901. For example, in a hypothetical case where computer 901 is designed and programmed to provide a recommendation based on historical data, then this historical data may be provided to computer 901 from remote database 930 of remote server 904.

PUBLIC CLOUD 905 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 905 is performed by the computer hardware and/or software of cloud orchestration module 941. The computing resources provided by public cloud 905 are typically implemented by virtual computing environments that run on various computers making up the computers of host physical machine set 942, which is the universe of physical computers in and/or available to public cloud 905. The virtual computing environments (VCEs) typically take the form of virtual machines from virtual machine set 943 and/or containers from container set 944. It is understood that these VCEs may be stored as images and may be transferred among and between the various physical machine hosts, either as images or after instantiation of the VCE. Cloud orchestration module 941 manages the transfer and storage of images, deploys new instantiations of VCEs and manages active instantiations of VCE deployments. Gateway 940 is the collection of computer software, hardware, and firmware that allows public cloud 905 to communicate through WAN 902.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 906 is similar to public cloud 905, except that the computing resources are only available for use by a single enterprise. While private cloud 906 is depicted as being in communication with WAN 902, in other embodiments a private cloud may be disconnected from the internet entirely and only accessible through a local/private network. A hybrid cloud is a composition of multiple clouds of different types (for example, private, community or public cloud types), often respectively implemented by different vendors, Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 905 and private cloud 906 are both part of a larger hybrid cloud.

The computer 901 in some embodiments also hosts one or more machine learning models such as the generative machine learning model. A machine learning model in one embodiment is stored in the persistent storage 913 of the computer 901. A received data sample is input to the machine learning model via an intra-computer transmission within the computer 901, e.g., via the communication fabric 911, to a different memory region hosting the machine learning model.

In some embodiments, one or more machine learning models such as an AIOPs model are stored in computer memory of a computer positioned remotely from the computer 901, e.g., in a remote server 904 or in an end user device 903. In this embodiment, the program 916 works remotely with this machine learning model to access same. Prompts are sent via a transmission that starts from the computer 901, passes through the WAN 902, and ends at the destination computer that hosts the machine learning model. Thus, in some embodiments the program 916 at the computer 901 or another instance of the software at a central remote server performs routing of machine learning input to multiple server/geographical locations in a distributed system.

In such embodiments, a remote machine learning model such as an AIOps model is configured to send its output back to the computer 901 so that the code evaluation output from using the trained model to analyze newly generated code is provided and presented to a user. The machine learning model receives a copy of the new code, performs machine learning analysis on the received sample, and transmits the results, e.g., an output back to the computer 901.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” “includes,” “including,” “has,” “have,” “having,” “with,” and the like, when used in this specification, specify the presence of stated features, integers, steps, operations, elements, and/or components, but does not preclude the presence or addition of one or more other features, integers, steps, operations, elements, components, and/or groups thereof.

The descriptions of the various embodiments of the present invention have been presented for purposes of illustration but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

The flowchart and block diagrams in the Figures illustrate the architecture, functionality, and operation of possible implementations of systems, methods, and computer program products according to various embodiments. In this regard, each block in the flowchart, pipeline, and/or block diagrams may represent a module, segment, or portion of instructions, which comprises one or more executable instructions for implementing the specified logical function(s).

What is claimed is:

1. A computer-implemented method comprising:
generating a first digital twin that models a first computing application being carried out in a first computing configuration, wherein the first digital twin replicates settings of the first computing configuration;
generating a second digital twin by altering the first digital twin;
gathering respective time series data from the first digital twin, from the second digital twin, and from the first computing configuration;
detecting drift in the gathered time series data so that different groups of data are produced; and
training an AIOps model by implementing meta-learning domain generalization and by using training data divided according to the different groups of data.

2. The method of claim 1, further comprising:
applying the trained AIOps model to a target computing environment to predict performance of the first computing application in the target computing environment.

3. The method of claim 1, wherein the applying occurs as zero shot learning with respect to the target computing environment.

4. The method of claim 1, wherein the target computing environment is a cloud configuration.

5. The method of claim 1, wherein the altering of the first digital twin comprises performing a first intervention comprising at least one of scaling or throttling the generated first digital twin.

6. The method of claim 1, wherein the drift is detected in both intra-time-series and inter-time-series scenarios in the gathered time series data to produce the different groups of data.

7. The method of claim 1, wherein the drift is detected in the time series data via a sliding window portioning approach.

8. The method of claim 1, wherein the drift is detected in the time series data via application of at least one statistical test applied to sub-series of the gathered respective time series data that were split.

9. The method of claim 1, wherein the meta-learning domain generalization comprises:
splitting the different groups of data as separate domains into one or more meta train domains and into one or more meta test domains;
calculating a gradient and updating the AIOps model for the meta train domains;
calculating a loss for the AIOps model for the meta test domains; and
updating the AIOps model considering a combined loss from both the meta train domains training and the meta test domains training.

10. The method of claim 1, further comprising:
collecting data from an implementation of a computing application in the target computing environment; and
updating the AIOps model based on the collected data.

11. A computer system comprising:
a processor set;
a set of one or more computer-readable storage media; and
program instructions, collectively stored in the set of one or more storage media, configured to cause a processor set to perform computer operations comprising:
generating a first digital twin that models a first computing application being carried out in a first computing configuration, wherein the first digital twin replicates settings of the first computing configuration;
generating a second digital twin by altering the first digital twin;
gathering respective time series data from the first digital twin, from the second digital twin, and from the first computing configuration;
detecting drift in the gathered time series data so that different groups of data are produced; and
training an AIOps model by implementing meta-learning domain generalization and by using training data divided according to the different groups of data.

12. The computer system of claim 11, wherein the computer operations further comprise applying the trained AIOps model to a target computing environment to predict performance of the first computing application in the target computing environment.

13. The computer system of claim 11, wherein the applying occurs as zero shot learning with respect to the target computing environment.

14. The computer system of claim 11, wherein the target computing environment is a cloud configuration.

15. The computer system of claim 11, wherein the altering of the first digital twin comprises performing a first intervention comprising at least one of scaling or throttling the generated first digital twin.

16. A computer program product comprising:
a set of one or more computer-readable storage media; and
program instructions, collectively stored in the set of one or more storage media, configured to cause a processor set to perform computer operations comprising:
generating a first digital twin that models a first computing application being carried out in a first computing configuration, wherein the first digital twin replicates settings of the first computing configuration;
generating a second digital twin by altering the first digital twin;
gathering respective time series data from the first digital twin, from the second digital twin, and from the first computing configuration;
detecting drift in the gathered time series data so that different groups of data are produced; and
training an AIOps model by implementing meta-learning domain generalization and by using training data divided according to the different groups of data.

17. The computer program product of claim 16, wherein the drift is detected in both intra-time-series and inter-time-series scenarios in the gathered time series data to produce the different groups of data.

18. The computer program product of claim 16, wherein the drift is detected in the time series data via a sliding window portioning approach.

19. The computer program product of claim 16, wherein the drift is detected in the time series data via application of at least one statistical test applied to sub-series of the gathered respective time series data that were split.

20. The computer program product of claim 16, wherein the meta-learning domain generalization comprises:
splitting the different groups of data as separate domains into one or more meta train domains and into one or more meta test domains;
calculating a gradient and updating the AIOps model for the meta train domains;
calculating a loss for the AIOps model for the meta test domains; and
updating the AIOps model considering a combined loss from both the meta train domains training and the meta test domains training.
